(19) United States
(12) Patent Application Publication
(10) Pub. No.: US 2006/0289979 A1
(43) Pub. Date: Dec. 28, 2006

(54) Bridge modules for smart labels

(76) Inventor: God Ralf, Dresden (DE)

Correspondence Address: BLACK LOWE & GRAHAM, PLLC, 701 FIFTH AVENUE, SUITE 4800, SEATTLE, WA, 98104, US

(21) Appl. No.: 10/569,165

(22) PCT Filed: Aug. 24, 2004
(86) PCT No.: PCT/EP04/09420

§ 371 Date: Feb. 24, 2006

(30) Foreign Application Priority Data
Aug. 26, 2003 (DE) 10339547.4
Dec. 13, 2003 (DE) 10358423.4

(51) Int. Cl. H01L 23/02

(52) U.S. Cl. 257/679

(57) ABSTRACT

The invention relates to module bridges for smart labels for positioning chip modules (5) on carries (12) and for the bridging connection of connection elements of the chip modules (5) to connection elements (11a, 11b) of antenna elements (11) arranged on or in the carriers (12), a plurality of module bridges (10) are arranged one behind the other on a carrier strip (1), wherein the carrier (1) has a plurality of depressions (2) arranged one behind the other for respectively receiving a chip module (5) assigned to a module bridge (10) and printed contact layers (7a, 7b), which cover the connection elements of the chip modules (5), with increased dimensions compared to the dimensions of the connection elements.

### DESCRIPTION

The invention relates to module bridges for smart labels for positioning chip modules on carriers and for the bridging connection of connection elements of the chip modules to connection elements of antenna elements arranged on or in the carriers, according to the preamble of claim 1.

Smart labels, which in addition to an antenna also comprise a RFID chip (Radio Frequency Identification chip), preferably made of silicon, are produced in large numbers at a high production speed. Conventionally, the dimensions of such chips are becoming smaller and smaller as they are developed, so that precise positioning of the chip on an antenna substrate in relation to connection elements of an antenna element is becoming increasingly difficult and more complicated in terms of the device used.

To date, the RFID chips have been applied to the antenna substrate by means of so-called pick-and-place methods in a flip-chip technique. In this case, a high-precision robot removes a silicon chip from a silicon wafer, rotates said chip through 180° so that the top of the silicon chip with the connection elements arranged thereon points downwards, and mounts the chip in this upside-down position on the antenna and the antenna substrate. In this method, the connection elements of the chip, which are of very small dimensions, must be brought with high precision into a position corresponding to the connection elements of the antenna.

Since the antenna substrates with the antennas are usually located on wide, flexible webs having a width of approx. 500 mm during the smart label production process, a complicated robot design is required for precise placement of the chips on the antenna substrates. Usually, placement accuracies in a range of 10-20 μm are required here.

Such robot designs, which have to operate in the high-precision range over relatively large distances, on the one hand exhibit a high number of precision errors and on the other hand considerably reduce the processing speed during the operation of mounting the chip on the antenna substrate. This in turn leads to a reduction in the overall production speed during the manufacture of smart labels, and to high production costs.

It is known that individual module bridges are used as bridging connections between the small connection elements of the chip modules and the connection elements of the antenna. Such module bridges have contact lines which extend from the inside out. The inner ends are connected to a chip module arranged on the module bridge and the outer ends are provided for establishing contact with the connection elements of the antenna.

In order to arrange chip modules on the antenna substrates by means of the module bridges, the chip modules are pre-mounted in a spatially limited small operating field on the module bridges in the high-precision method, and these are then mounted within a large operating field on the antenna substrates or antennas with reduced accuracy and at high speed. The module bridges usually used for this are made of expensive plastics materials and are manufactured individually before pre-mounting of the chip module takes place.

Accordingly, the object of the present invention is to provide module bridges for smart labels for positioning chip modules on carriers, which can be manufactured in a quick and cost-effective manner and which permit rapid and simple high-precision mounting of the chip modules on different carriers.

This object is achieved according to the invention by the features of Claim 1.

One essential point of the invention is that, in module bridges for smart labels for positioning chip modules on carriers and for the bridging connection of connection elements of the chip modules to connection elements of antenna elements arranged on or in the carriers, a plurality of module bridges are arranged one behind the other on a carrier strip, wherein the carrier strip has a plurality of depressions arranged one behind the other for respectively receiving a chip module assigned to a module bridge and contact layers, which cover the connection elements of the chip modules, with increased dimensions compared to the dimensions of the connection elements.

By virtue of the simple configuration according to the invention of a plurality of module bridges on the carrier strip by means of the contact layers, which extend over the previously arranged chip modules in a simple manner for example by means of a printing process, rapid and simple manufacture of a large amount of module bridges in an endless strip is possible without incurring high material costs in the process. Rather, the carrier strip material used may be cost-effective plastics or paper materials which can be shaped in a three-dimensional manner by employing appropriate shaping techniques, such as thermoplastic deformation or a stamping technique for example. This shaping technique can also be carried out rapidly and simply in a continuous manner within a device while the carrier strip is continuously moved or temporarily stopped.

The formation of depressions within the carrier strip permits the rapid insertion of the chip modules with their connection elements oriented upwards, said connection elements being covered preferably by two strip-like contact layers which run parallel to one another and have interruptions between the chip modules. Since the contact layers have larger surface dimensions than the connection element of the individual chip module, it is possible to mount such a module bridge on the connection elements of the antenna element with a relatively high degree of inaccuracy, said antenna element being arranged on the carrier, which may be designed as an antenna substrate. Consequently, this advantageously results in rapid and simple mounting of the module bridges containing the chip modules on the antenna substrates within a large operating field.

The high-precision procedure required to date in a small operating field in connection with pre-mounting a chip module on a module bridge is also no longer required with such a degree of precision since the chip modules are simply placed in the depressions and simply covered with the contact layers. The simple design of the module bridges also proves to be advantageous in terms of separating them from the carrier strip, in which the individual module bridges can be exposed in a simple and rapid manner for example by means of a longitudinal cutting operation in the longitudinal direction of the carrier strip or by cutting through remaining half-webs in the transverse direction of the carrier strip. The essential thing here is that, between the chip modules, both the carrier strip and the contact layer have interruptions which extend in the transport width direction.

According to one preferred embodiment, applied to the contact layers are adhesive layers for adhesively attaching individual module bridges to the carriers in the region of the connection elements of the antenna element. The adhesive layers preferably consist of two strip-like adhesive layers which run parallel to one another in the longitudinal direction of the carrier strip and have interruptions which coincide with the interruptions within the carrier strip and the contact layers.

Alternatively, the contact layers may be designed to be self-adhesive. To this end, they may consist either of prepolymerized epoxy resin with conductive particles contained therein or of a hot-melt adhesive with conductive particles contained therein.

The contact layers consist of a first strip-like contact layer which extends in the direction of the carrier strip and covers the first connection elements of first connection sides of the chip modules, and of a second strip-like contact layer which extends in the longitudinal direction of the carrier strip and covers the second connection elements of second connection sides of the chip modules. In this way, rapid application of the two contact layers running parallel to one another is possible during transport of the carrier strip by printing with a silver paste. As a result, enlarged connection surfaces for the chip modules are obtained.

According to one preferred embodiment, the chip modules are arranged within the depressions by means of adhesive, so that there is a durable connection between the carrier strip and the chip modules.

Preferably, the depressions have a sufficient depth for arranging the chip modules therein in such a way that their upper sides and a surface of the carrier strip which surrounds the depressions lie in one plane. This therefore ensures that the contact layers extending both over the upper sides of the chip modules and over the surface of the carrier strip extend in one piece without any undesired interruptions within a plane.

The depressions are shaped to be complementary to outer shapes of the chip modules to be received therein, in order to ensure an optimal and fitting placement of the chip modules within the carrier strip. In this way, by using the appropriate tool, the carrier strip can be deformed or stamped in such a way that almost any type of chip module can be positioned therein. Moreover, self-centering of the chip module takes place as the chip module is placed into the shaped depression.

The depressions may in each case optionally be provided with at least one hole on the underside, on which hole the chip module is arranged. The punching of such a hole is advantageous when a curing operation is required for the adhesive, since it makes it possible for the adhesive to be acted upon directly, for example by UV light.

Further advantageous embodiments emerge from the dependent claims.

Advantages and expedient features can be found from the following description in conjunction with the drawing, in which:

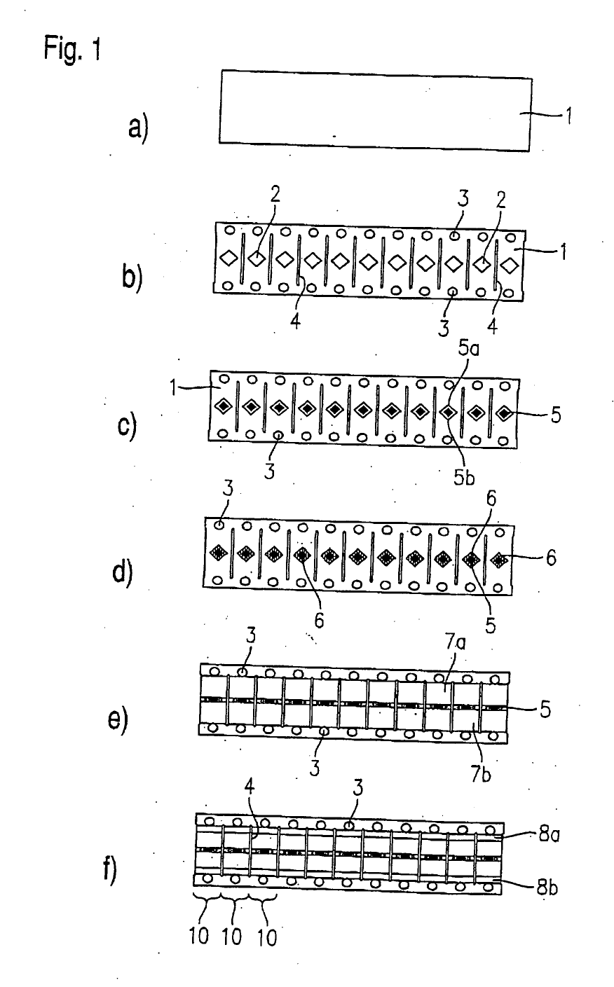

FIGS. 1a-1f show in sequence the formation of the module bridges according to the invention in plan view;

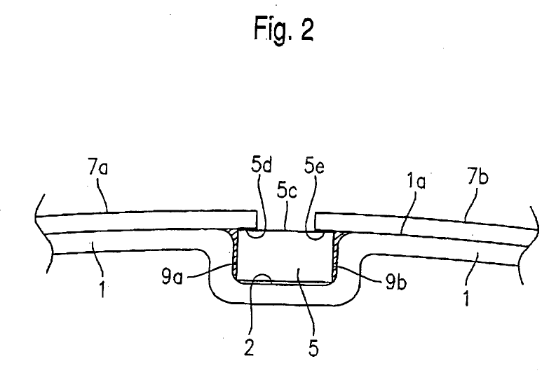

FIG. 2 shows, in a schematic cross-sectional view, the structure of a module bridge including a chip module; and

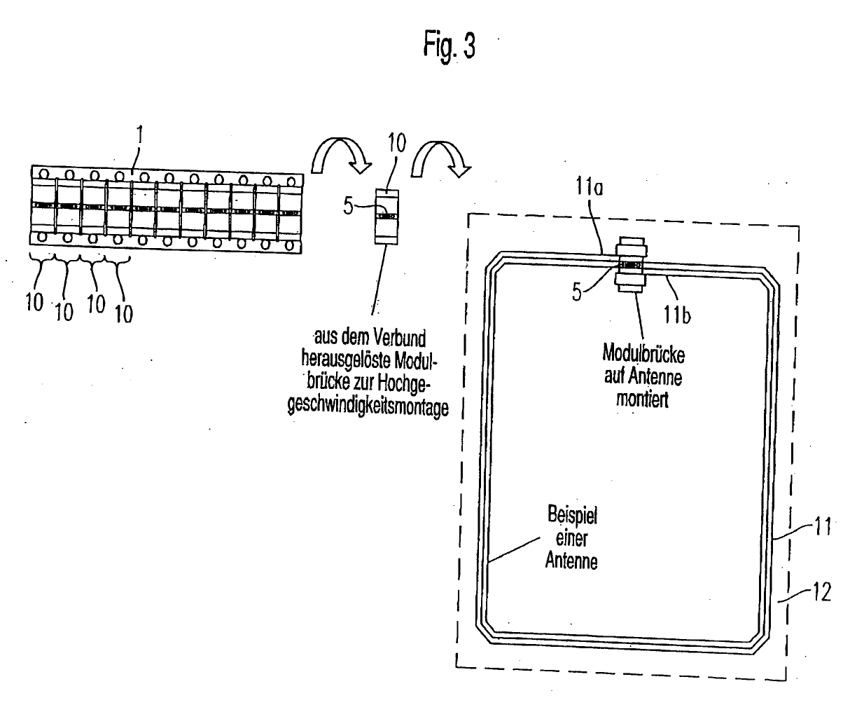

FIG. 3 shows, in a schematic plan view, the positioning of a module bridge according to the invention with a chip module on connection elements of an antenna element.

FIGS. 1a-1c respectively show, in plan view and in sequence, the formation of the module bridges according to the invention. Following a thermoplastic deformation, a stamping process and/or a punching process, a carrier strip (shown in FIG. 1a) made of a plastics and/or paper material has depressions 2 arranged one behind the other for receiving chip modules, said depressions possibly having through-holes. Rows of holes 3 arranged at the edges serve to move the carrier strip 1 forward within a device by means of a transport element (not shown here).

Arranged between the depressions 2 are three slot-like interruptions 4 within the carrier strip 1, said interruptions extending in the width direction of the carrier strip and being advantageous for subsequently separating the module bridges from the module bridge composite.

FIG. 1c shows that chip modules 5 with first and second connection sides 5a and 5b are inserted in the depressions 2. In order to fix the chip modules, the latter are inserted within a deposit of adhesive arranged in the depression 2, as shown by reference 6 in FIG. 1d. This adhesive is cured by means of UV irradiation, electron beam irradiation or thermal irradiation.

As can be seen from FIG. 1e, there is a first strip-like contact layer 7a which extends over the first connection side 5a of the chip modules 5. A second contact layer 7b extends parallel to the first contact layer 7a, and again in a strip-like manner, over the second connection side of the chip modules. The surface dimensions of the contact layers 7a and 7b are larger than the dimensions of connection elements of the chip modules.

Both the first and the second contact layer 7a and 7b have interruptions 4 which coincide with the interruptions of the carrier strip 1. In order to permit a mechanical and optionally also additional electrical connection of the module bridges 10 to connection elements of an antenna element, the module bridges 10 arranged one behind the other have two strip-like adhesive layers 8a and 8b arranged parallel to one another, again with interruptions 4.

FIG. 2 shows, in a schematic cross-sectional diagram, a module bridge according to the invention with the chip module 5. As can be seen from this diagram, the chip module 5 is arranged within the depression 2 of the carrier strip 1 in such a way that its upper side 5c lies in one plane with a surface 1a of the carrier strip 1 which surrounds the depression 2. There are additionally parts of adhesive 9a and 9b which fix the chip module 5.

The contact layers 7a and 7b extend over the connection elements 5d and 5e (shown schematically) of the chip module 5 and the surface 1a of the carrier strip.

Advantageously, on account of this design of a module bridge according to the invention, bending of the module bridge can be carried out without this causing a loss of contact between the connection elements 5d, 5e and the contact layers 7a and 7b.

FIG. 3 shows, in a schematic diagram, the positioning of an individual module bridge with a chip module on connection elements of an antenna element. As can be seen from FIG. 3, an individual module bridge 10 including the chip module 5 and part of the carrier strip is cut out of the module bridge composite and, with the adhesive layers 8a and 8b facing downwards, is placed on and fixed to connection elements 11a and 11b of the antenna 11. An antenna substrate 12 is shown schematically.

All the components and features disclosed in the application documents are to be considered essential to the invention both individually and in combination.

### List of References

1 carrier strip
1a surface of the carrier strip
2 depressions
3 rows of holes
4 slot-like interruptions
5 chip modules
5a first connection side
5b second connection side
5c upper side of the chip module
5d, 5e connection elements of the chip module
6 cured adhesive
7a first strip-like contact layer
7b second strip-like contact layer
8a first strip-like adhesive layer
8b second strip-like adhesive layer
9a, 9b parts of adhesive
10 module bridges
11 antenna element
11a, 11b connection element of the antenna element
12 antenna substrate

What is claimed is:

1. A module bridge system for smart labels for positioning chip modules (5) on carriers (12) and for the bridging connection of connection elements of the chip modules (5) to connection elements (11a, 11b) of antenna elements (11) arranged on or in the carriers (12), the module bridge system comprising:
a carrier strip; and
a plurality of module bridges (10) are arranged one behind the other on the carrier strip (1), wherein the carrier strip (1) has a plurality of depressions (2) arranged one behind the other for respectively receiving a chip module (5) assigned to a module bridge (10) and printed contact layers (7a, 7b), which cover the connection elements of the chip modules (5), with increased dimensions compared to the dimensions of the connection elements.

2. The module bridge system of claim 1, further comprising
adhesive layers (8a, 8b) applied to the printed contact layers (7a, 7b) for adhesively attaching individual module bridges (10) to the carriers (12) in the region of the connection elements (11a, 11b) of the antenna elements (11).

3. The module bridge system of claim 1, wherein the printed contact layers (7a, 7b) are designed to be self-adhesive.

4. The module bridge system of claim 1, wherein the printed contact layers (7a, 7b) consist of a first strip-like contact layer which extends in a longitudinal direction of the carrier strip and covers first connection elements of first connection sides (5a) of the chip modules (5), and of a second strip-like contact layer which extends in the longitudinal direction of the carrier strip and covers second connection elements of second connection sides (5b) of the chip modules (5).

5. The module bridge system of claim 4, wherein the first and second strip-like contact layers (7a, 7b) have interruptions (4) between the chip modules (5), said interruptions extending in the width direction of the carrier strip.

6. The module bridge system of claim 2, wherein the adhesive layers (8a, 8b) consist of two strip-like adhesive layers (8a, 8b) with interruptions (4), said layers running parallel to one another in the longitudinal direction of the carrier strip.

7. The module bridge system of claim 1, wherein the chip modules (5) are arranged within the depressions (2) by means of adhesive (9a, 9b).

8. The module bridge system of claim 1, wherein the depressions (2) have a sufficient depth for arranging the chip modules (5) therein in such a way that their upper sides (5c) and a surface (1a) of the carrier strip (1) which surrounds the depressions (2) lie in one plane.

9. The module bridge system of claim 1, wherein the depressions (2) are shaped to be complementary to outer shapes of the chip modules (5) to be received therein.

10. The module bridge system of claim 1, wherein the depressions (2) in each case have at least one hole on the underside.

11. The module bridge system of claim 1, wherein the transport strip (1) has rows of holes (3) at the edge for the engagement of transport elements.

12. The module bridge system of claim 1, wherein the carrier strip (1) is made of at least one of a deformable plastic and paper material.
